(19) United States
(12) Patent Application Publication
(10) Pub. No.: US 2011/0281156 A1
(43) Pub. Date: Nov. 17, 2011

(54) Vertically Aligned Carbon Nanotube Augmented lithium Ion Anode for Batteries

(76) Inventors: Arthur Douglas Boren, San Jose, CA (US); Darin Scott Olson, Newark, CA (US)

(21) Appl. No.: 13/109,017

(22) Filed: May 17, 2011

Related U.S. Application Data
(60) Provisional application No. 61/395,695, filed on May 17, 2010.

(51) Int. Cl. H01M 10/02; H01M 4/583; H01M 10/04; B05D 1/36; C23C 16/26; C23C 16/30; C23C 16/50; H01M 4/66; B05D 5/12; B82Y 40/00; B82Y 30/00

(52) U.S. Cl. 429/188; 429/211; 427/122; 427/578; 977/748; 977/745; 977/842

(57) ABSTRACT

An electrode for a battery is augmented with vertically aligned carbon nanotubes, allowing both improved storage density of lithium ions and the increase electrical and thermal conductivity. Carbon nanotubes are extremely good electrical and thermal conductors, and can be grown directly on the electrode (e.g., anode or cathode) current collector metals, allowing direct electrical contact. Additionally carbon nanotubes have an ideal aspect ratio, having lengths potentially thousands of times as long as their widths, 10 to 1,000 nanometers. In an embodiment, the carbon nanotube electrode (e.g., an anode) comprises a silicon matrix, allowing withstanding volumetric changes exhibited during cycling of the electrochemical cell. In an embodiment, the carbon nanotube electrode (e.g., a cathode) comprises embedded sulfur, allowing both the improved retention of elemental sulfur and increase electrical conductivity.

This application claims priority from U.S. provisional patent application Ser. No. 61/395,695, filed on May 17, 2010, entitled “Vertically Aligned Carbon Nanotube Augmented lithium Ion Anode for Batteries”, which is incorporated herein by reference. The present application is related to co-pending application Ser. No. 13/092,274, filed on Apr. 22, 2011, entitled “Carbon Nanotube Augmented Sulfur Cathode for an Elemental Sulfur Battery”, which is incorporated herein by reference.

### BACKGROUND

Current lithium battery technology is predominately lithium ion based, in this case one of the primary limitations of the energy density of the battery is the density of the lithium ion storage at the anode. The battery technology energy density is limited, in part, by the limited ability to store high densities of lithium ions at the anode. One of the best candidates for lithium ion storage is silicon, however, multiple cycles of lithium ion diffusion into and out of the silicon causes bulk silicon to break apart because of the volume expansion with lithium adsorption, becoming a powder, no longer in electrical contact with the rest of the battery. One approach to solve the problem is to use silicon nanowires to store the lithium ions, allowing volume expansion without mechanical failure. However, silicon nanowires are not ideal for this application as they have some internal resistance, cannot transmit heat as easily as other materials, and are difficult to grow.

### SUMMARY

The present invention discloses electrodes for batteries, and batteries utilizing the electrodes, wherein the electrode comprises carbon nanotubes (CNT) chemically bonded to a current collector.

In an embodiment, the present electrode is augmented with vertically aligned carbon nanotubes, allowing both the improved storage density, for example of lithium ions, over existing lithium salts, and the increase electrical and thermal conductivity. CNTs are extremely good electrical and thermal conductors, and can be grown directly on the electrode (e.g., anode or cathode) current collector metals, allowing direct electrical contact.

In an embodiment, the present CNT electrode (e.g., an anode) comprises silicon or silicon compound, allowing the repeated discharging and recharging (cycling) of a lithium ion battery. Additionally CNTs have an ideal aspect ratio, having lengths potentially thousands of times as long as their widths, 10 to 1,000 nanometers, allowing a lithium ion anode to be penetrated and crisscrossed with innumerable number of low resistance electron paths from the anode lead.

In an embodiment, the present invention discloses an electrochemical cell, such as a battery, which can provide high energy capacity through the carbon nanotubes. For example, silicon coated carbon nanotubes can absorb the Lithium during a charge state of the battery and to release the Li⁺ ions during a discharge state. The silicon-coated carbon nanotubes each has silicon on an outer surface that interact with the ions. The cell further comprises an ion transporter to provide ions, such as lithium ions. In an embodiment, the electrochemical cell further comprises a separator and a second electrode comprising a state-of-the-art cathode. In an embodiment, the electrochemical cell further comprises a separator and a second electrode comprising carbon nanotubes with embedded elemental sulfur.

### BRIEF DESCRIPTION OF THE DRAWINGS

FIG. 1 illustrates a schematic cross-sectional view of a silicon-coated CNT anode electrode according to an embodiment of the present invention.

FIG. 2 illustrates a schematic cross-sectional view of another silicon-coated CNT anode electrode according to an embodiment of the present invention.

FIG. 3 illustrates a schematic cross-sectional view of another silicon-coated CNT anode electrode according to an embodiment of the present invention.

FIG. 4 illustrates a sulfur-embedded CNT cathode electrode according to an embodiment of the present invention.

FIG. 5 illustrates a schematic cross-sectional view of another sulfur-embedded CNT cathode electrode according to an embodiment of the present invention.

FIG. 6 illustrates a schematic cross-sectional view of another sulfur-embedded CNT cathode electrode according to an embodiment of the present invention.

FIG. 7 illustrates a battery according to an embodiment of the present invention.

FIG. 8A illustrates an exemplary flowchart of the silicon-coated CNT anode according to an embodiment of the present invention.

FIG. 8B illustrates an exemplary flowchart of the sulfur embedded CNT cathode according to an embodiment of the present invention.

FIG. 9A illustrates an exemplary reel-to-reel system for silicon-coated CNT electrode according to an embodiment of the present invention.

FIG. 9B illustrates an exemplary reel-to-reel system for sulfur-embedded CNT electrode according to an embodiment of the present invention.

### DETAILED DESCRIPTION OF THE PREFERRED EMBODIMENTS

The present invention is related to different types of batteries and devices involving nanostructure electrodes. In an embodiment, the present invention discloses a vertically aligned carbon nanotube (CNT) augmented electrode, to be used as a base for a silicon coated anode or an embedded sulfur cathode, to improve the performance of a lithium ion battery, and allows the repeated discharging and recharging (cycling) of a lithium ion battery.

A typical electrochemical cell stores and converts chemical energy from chemical oxidation and reduction reactions to electrical energy, with the reduction reactions occurring in the cathode and the oxidation reactions in the anode. The two electrodes are immersed in an ion transporter such as an electrolyte, and electrically connected to a current collector, where the external current is balanced by the flow of ions through the electrolyte. In lithium-ion batteries, Li ions are transported between electrodes for charging and discharging.

In an embodiment, the present invention discloses structures and methods using carbon nanostructures, e.g., at least one dimension in the nanometer dimension, for the battery electrode materials, such as carbon nanowires, carbon nanoparticles, and carbon nanotubes. The present description describes structures using carbon nanotubes, but the invention is not so limited, and carbon nanostructure can be used instead of carbon nanotubes.

In an embodiment, the present invention discloses an electrode (such as an anode or a cathode) augmented with carbon nanotubes, allowing both the improved storage density of lithium ions, over existing lithium salts, and the increase electrical and thermal conductivity. Additionally the CNTs allow the formation of a nanowire of any material selected as the lithium ion storage matrix, including silicon. Carbon nanotubes offer high strength-to-weight ratios and superior mechanical properties, in additional to excellent electrical and thermal conductivity. CNTs can be grown directly on the surface of a metal collector, allowing direct electrical contact, to produce nanoscale composites to be used as electrodes in battery, ultra capacitors, magnetic storage, fuel cell, and composite applications. Carbon nanotubes or carbon nanofibers have excellent electric conductivity, together with large surface area accessible by the ions of the electrolyte, thus offering low resistance to be used as electrode materials for battery applications. Additionally CNTs have an ideal aspect ratio, having lengths potentially thousands of times as long as their widths, 10 to 1,000 nanometers, allowing a lithium ion storage matrix to be penetrated and crisscrossed with an innumerable number of low resistance electron paths from the anode lead.

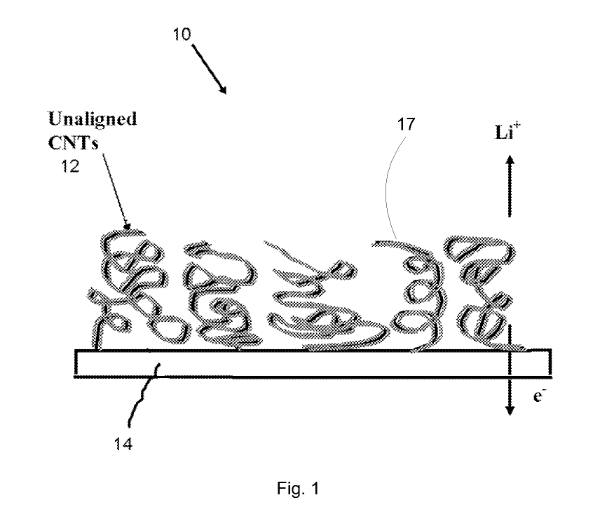

FIG. 1 illustrates a schematic cross-sectional view of a CNT electrode according to an embodiment of the present invention. The electrode 10 comprises CNTs 12 growing on a collector plate 14, thus CNTs are chemically bonded to the collector plate. The collector plate material can include materials that are not reactive with lithium, such as stainless steel, copper, nickel, and aluminum. The collector plate can also comprised of a flexible material with conductive coating such as a layer of metal. The collector plate can comprise a seed layer for growing CNTs. Silicon-containing material 17 is then coated on the carbon nanotubes 12, for example, by a deposition process such as PECVD or CVD. Silicon-containing materials can include polycrystalline silicon, amorphous silicon, or silicon compounds, such as SiGe or SiSn alloys. Alternatively, other materials that react (e.g., alloy) with lithium can be used in place of silicon, such as Sn, Bi and Al. The growth of silicon-containing material can include silane decomposition. The use of carbon nanotubes accommodates the volume change during lithium insertion in charging cycles, allowing batteries with high energy capacities without structural damage due to the volumetric changes exhibited during cycling of the electrochemical cell.

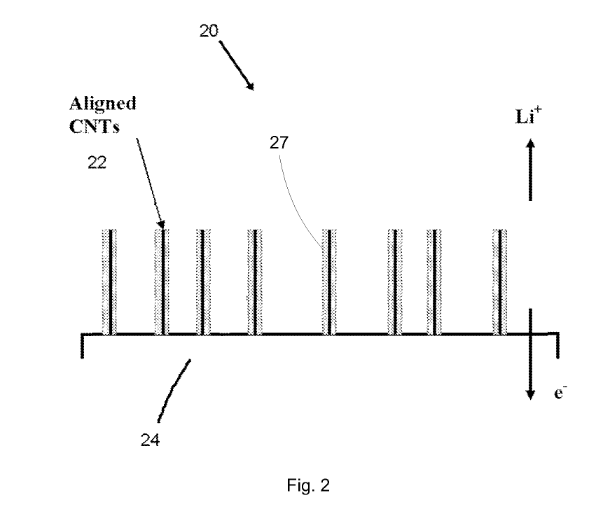

FIG. 2 illustrates a schematic cross-sectional view of another CNT electrode according to an embodiment of the present invention. The electrode 20 comprises vertically aligned CNTs 22 growing on a current collector 24, thus CNTs are chemically bonded to the collector plate. Silicon-containing material 27 is then coated on the carbon nanotubes 12, for example, by a deposition process such as PECVD.

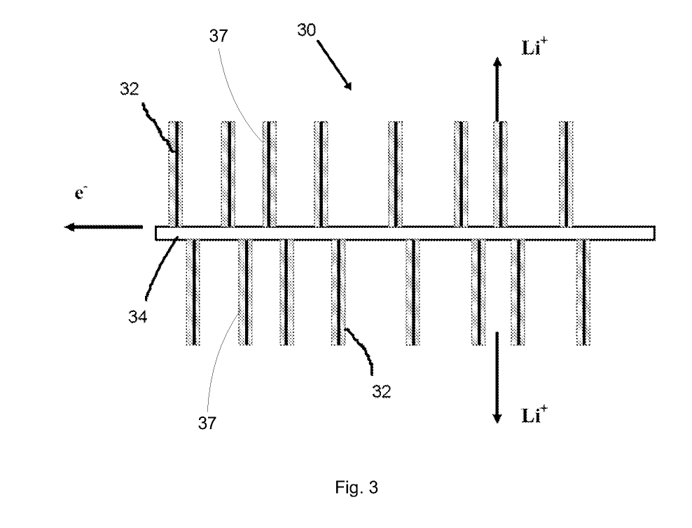

FIG. 3 illustrates a schematic cross-sectional view of another CNT electrode according to an embodiment of the present invention. The electrode 30 comprises vertically aligned CNTs 32 growing on both sides of a current collector 34, thus CNTs are chemically bonded to the collector plate. Silicon-containing material 37 is then coated on the carbon nanotubes 12, for example, by a deposition process such as PECVD.

The carbon nanotubes include single-walled carbon nanotubes (SWNTs), multi-walled carbon nanotubes (MWNTs), which may be prepared by any conventional process such as arc-discharge, laser vaporization, chemical vapor deposition (CVD) and high pressure decomposition of carbon monoxide (HiPCO). In an embodiment, seed layer or catalyst components can be provided on the collector plate to facilitate the growing of CNTs.

In an embodiment, the silicon-coated CNT is employed as a CNT augmented anode, supporting a lithium ion storage matrix and impregnated with lithium ions. The silicon-coated CNT augmented anode can be placed in contact with an electrolyte, which in turn is in contact with a cathode. This construction allows lithium ions (Li+) to flow from the anode to the cathode, while the electrolyte prevents the flow of electrons. Once the flow of electrons is allowed, through an external circuit, the lithium reacts with the cathode, forming intermediate and final lithium compounds. The more the reaction continues the more electrons flow through the external circuit until all of the available lithium ions, or cathode materials, react and the battery is discharged. The battery is recharged the same way except that the charger drives the battery in reverse, causing the lithium ions to cross back through the electrolyte and become bound in the lithium ion storage matrix material, combining with the supplied electrons to become lithium again.

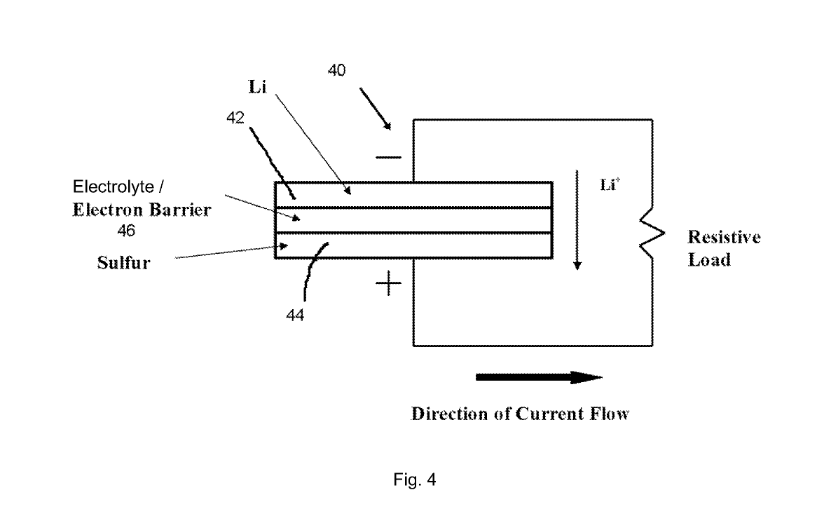

In an embodiment, the present invention discloses a battery employing a silicon-coated CNT anode. FIG. 4 illustrates a battery according to an embodiment of the present invention. The battery system 40 includes an anode 42, a cathode 44, and a separator 46. In an embodiment, either or both the anode 42 and cathode 44 comprise CNT materials, which can be any known nanostructure carbon material, and preferably vertically aligned CNTs. The silicon-coated CNT anode, having a silicon-containing matrix bonded with carbon nanotubes, would be placed in contact with an electrolyte, which in turn is in contact with the battery cathode. This construction allows lithium ions (Li⁺) to flow from the anode to the cathode, while the electrolyte prevents the flow of electrons. An electrolyte, acting as an ion transporter, allows ions to move between electrodes located on either side of the electrolyte.

In an embodiment, a silicon-coated CNT augmented electrode would consist of a “mat”, “forest”, or “mass” of carbon nanotubes grown, or otherwise bonded, directly on the cathode lead metal. This mat of CNTs would function as both the electrical path for electrons out of the electrode and as the physical substrate on which is grown the lithium ion storage matrix, e.g. silicon. A preferred construction process is to first grow, or bond, the CNTs to the electrode lead metal, then infuse or grow the storage matrix onto the CNT structure then infuse the storage matrix with lithium ions. The carbon nanotubes might be intermixed, or might be vertically aligned to the current collector plate. In addition, the same process maybe repeated on the other side of the current collector place, resulting with a structure having carbon nanotubes grown on both sides of the current collector.

The silicon-coated CNT anode can be used in conjunction with a cathode structure. In an embodiment, the present invention discloses a carbon nanotube (CNT) augmented sulfur cathode to improve the performance of elemental lithium sulfur (LiS) or lithium ion and sulfur battery, allowing the repeated discharging and recharging (cycling) of a lithium sulfur battery. The present elemental lithium sulfur battery could provide energy densities (power/pound) over four times those of batteries currently available.

In an embodiment, the present cathode augmented with carbon nanotubes can allow both the improved retention of elemental sulfur, over the meso-porous carbon case, and increase electrical conductivity. Carbon nanotubes are extremely good electrical conductors, and can be grown directly on cathode lead metals allowing direct electrical contact. Additionally CNTs have an ideal aspect ratio, having lengths potentially thousands of times as long as their widths, 10 to 1,000 nanometers, allowing an elemental sulfur cathode to be penetrated and crisscrossed with innumerable number of low resistance electron paths from the cathode lead. Additionally the surface of CNTs are nearly chemically identical to carbon, including meso-porous carbon, binding the sulfur atoms to the CNTs preventing the “loss” of sulfur with the formation of LiS intermediate products. In an embodiment, elemental sulfur is incorporated in the form of an active material comprising elemental sulfur.

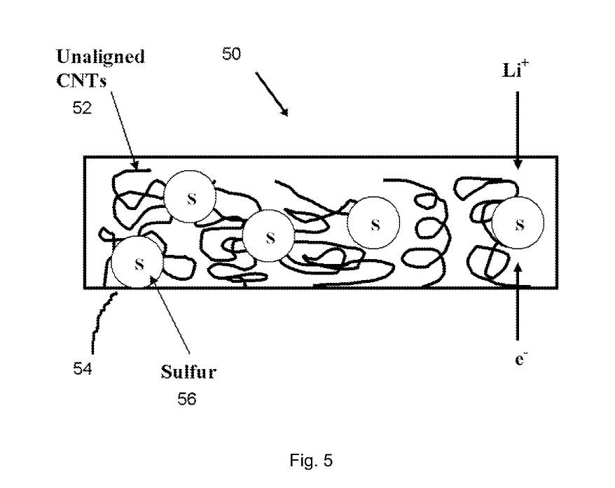

FIG. 5 illustrates a CNT cathode according to an embodiment of the present invention. A CNT augmented cathode 50 would consist of carbon nanotubes 52 grown, or otherwise bonded, directly on the cathode lead metal 54. This mat of CNTs would function as both the electrical path for electrons to the reacting sulfur and the physical substrate to which the sulfur is bound. A preferred construction process is to first grow, or bond, the CNTs 52 to the cathode lead metal 54, then infuse the mat with elemental sulfur 56.

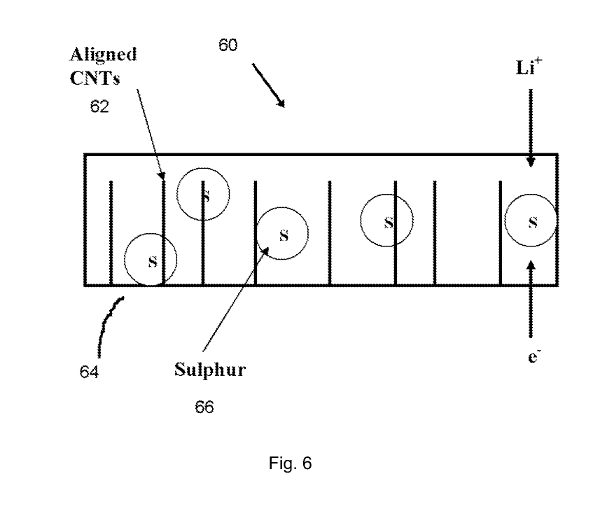

FIG. 6 illustrates a schematic cross-sectional view of another CNT cathode according to an embodiment of the present invention. The cathode 60 comprises vertically aligned CNTs 62 growing on a collector plate 64, thus CNTs are chemically bonded to the collector plate. Elemental sulfur 66 is infused to the CNTs, for example, by applying molten sulfur to the CNT surface.

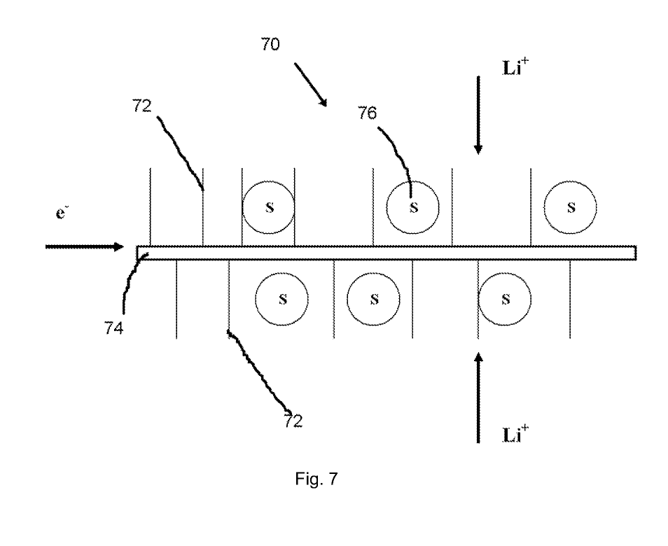

FIG. 7 illustrates a schematic cross-sectional view of another CNT cathode according to an embodiment of the present invention. The cathode 70 comprises vertically aligned CNTs 72 grown on both sides of a collector plate 74 with elemental sulfur 76 bonded to the CNTs. Once the flow of electrons is allowed, through an external circuit, the lithium reacts with the elemental sulfur, forming intermediate and final lithium-sulfur compounds. The more electrons flow through the external circuit the more the reaction continues until all of the available sulfur reacts with all of the available lithium and the battery is discharged. The battery is recharge the same way except that the charger drives the battery in reverse, causing the lithium ions to cross back through the electrolyte and combine with supplied electrons to become elemental lithium again. The CNTs are also capable of absorbing and desorbing lithium (or other components) in an electrochemical system, with lithium metal powder dispersed in the CNT of the anode.

The CNT augmented cathode for an elemental sulfur battery can be used wherever battery applications require high energy densities (power to weight ratio) or high energy potentials are desired. The anode can be a CNT anode, having embedded lithium or lithium ions.

In an embodiment, the carbon nanotubes are grown by PECVD process. The PECVD process can grow CNTs on one side, or on two sides simultaneously. A seed layer can be deposited first on a collector plate for facilitate the growth of CNTs. In an embodiment, after the formation of CNTs, sulfur can be applied to the CNTs, for example, by pouring molten sulfur on the CNTs. Optional barrier layer can be applied afterward before applying the opposite electrode.

In an embodiment, the silicon matrix is silicon crystals, which can be multicrystals (polycrystalline silicon) or amorphous silicon, grown or deposited on the CNTs in a separate step. The CNT then serves as anchor for the silicon to the current collector, electron path for the electrons, and mechanical substrate for the CVD growth of silicon on the CNTs.

After the growth of the silicon, for example, by CVD or PECVD process, the lithium can be driven to the silicon matrix through a charging process. One way to drive the lithium into the silicon matrix structure is to drive it in with a voltage from an electrolyte solution, similar to how it would be recharged in the finished battery. The silicon absorbs the lithium, the volume increases, and the structure then is usable as an anode. Discharging causes the lithium to leave, recharging drives the lithium back in.

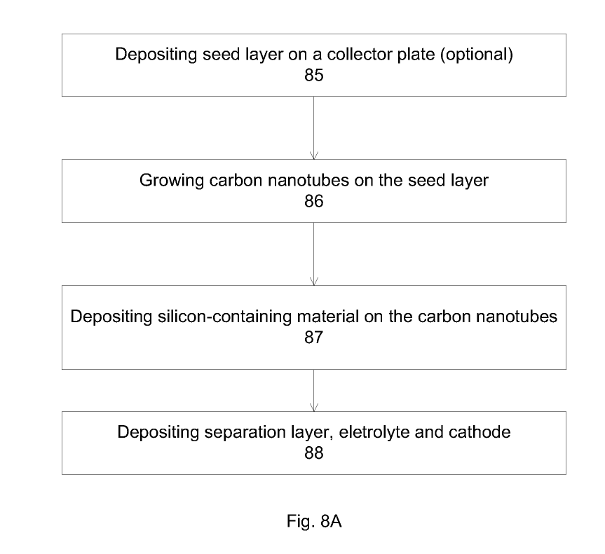

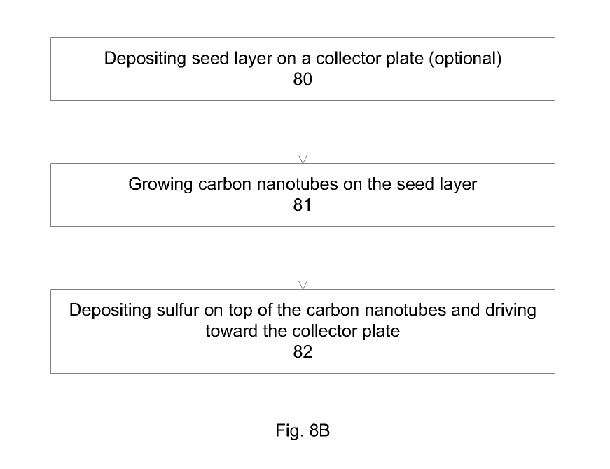

FIG. 8A illustrates an exemplary flowchart of the silicon-coated CNT anode according to an embodiment of the present invention. In operation 85, optional seed layer is deposited on a first collector plate. In operation 86, CNTs are grown on the seed layer, for example, by a PECVD process. In operation 87, silicon-containing material is deposited on the CNTs. In operation 87, separation layer, electrolyte and cathode are applied to form a battery.

The silicon-coated CNT anode can be followed with a sulfur-embedded CNT cathode to form a battery. FIG. 8B illustrates an exemplary flowchart of the sulfur embedded CNT cathode according to an embodiment of the present invention. In operation 80, optional seed layer is deposited on a second collector plate. In operation 81, CNTs are grown on the seed layer, for example, by a PECVD process. In operation 82, molten sulfur is applied on top of the CNTs, which can be driven to the CNTs.

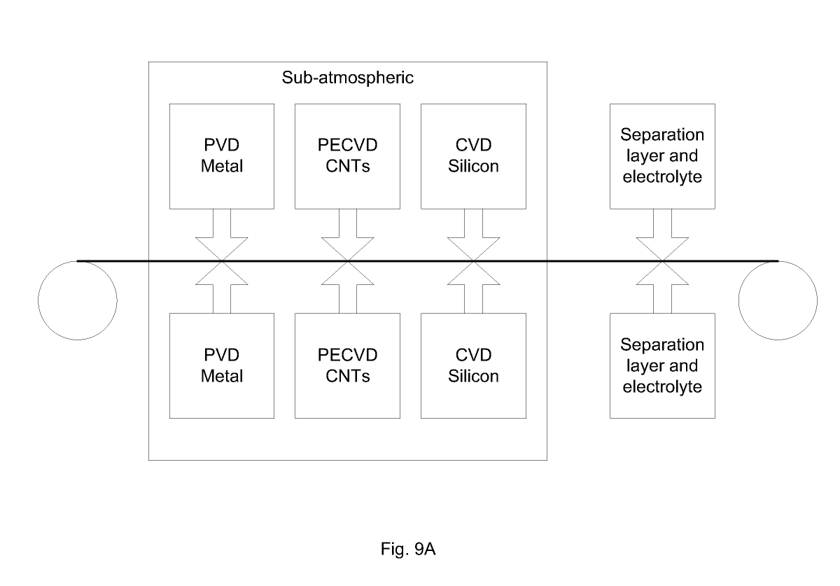

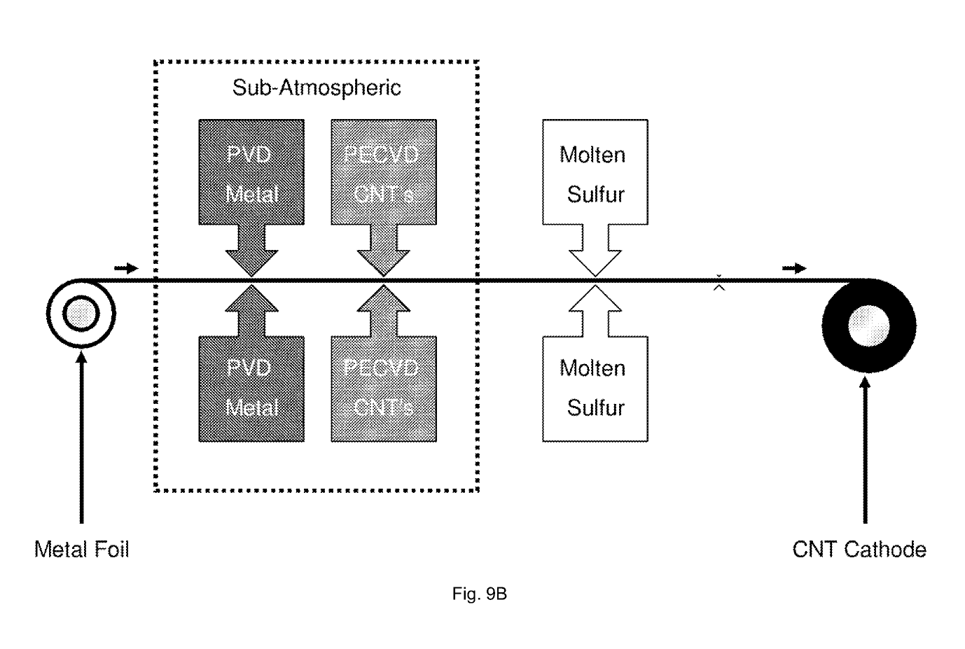

In an embodiment, a reel-to-reel process can be used for preparing the CNT augmented electrodes. FIG. 9A illustrates an exemplary reel-to-reel system for silicon-coated CNT anodes according to an embodiment of the present invention. A metal foil roll is running through multiple stations for sequential processing. In sub-atmospheric environment, a PVD system can deposit a seed metal layer, a PECVD system can deposit carbon nanotubes on the seed metal layer, and a CVD silicon can deposit silicon material on the carbon nanotubes. The carbon nanotubes are preferably vertically aligned to the metal seed layer. The silicon-coated CNT material can be formed on one side or on two sides of the metal foil. Afterward, the metal foil exits the sub-atmospheric environment, and enters a station to apply separation layer and electrolyte.

FIG. 9B illustrates an exemplary reel-to-reel system for sulfur-embedded CNT cathodes according to an embodiment of the present invention. A metal foil roll is running through multiple stations for sequential processing. In sub-atmospheric environment, a PVD system can deposit a seed metal layer and a PECVD system can deposit carbon nanotubes on the seed metal layer. The carbon nanotubes are preferably vertically aligned to the metal seed layer. Afterward, the metal foil exits the sub-atmospheric environment, and enters a sulfur station to deposit sulfur on the carbon nanotubes. For example, molten sulfur can be applied to the CNTs, and sulfur is then driven to within the CNTs. The sulfur embedded CNT material can be formed on one side or on two sides of the metal foil.

While the present invention has been described above and in the claims that follow, those skilled in the art will recognize that many changes may be made thereto without departing from the spirit and scope of the present invention.

What is claimed is:

1. An electrode for use in an electrochemical cell, comprising
a collector plate;
carbon nanotubes grown on the collector plate, wherein the carbon nanotubes are chemically bonded to the surface of the collector plate; and
silicon-containing matrix grown on the carbon nanotubes.

2. An electrode as in claim 1 wherein the carbon nanotubes are grown on two opposite sides of the collector plate.

3. An electrode as in claim 1 wherein the carbon nanotubes are vertically aligned on the collector plate.

4. An electrode as in claim 1 wherein the silicon-containing matrix comprises polysilicon material.

5. An electrode as in claim 1 wherein the collector plate comprises a seed layer for growing the carbon nanotubes.

6. An electrode as in claim 1 wherein the collector plate is flexible and rolled to a reel.

7. An electrochemical cell comprising
an ion transporter to transport ions;
a first current collector on one side of the ion transporter;
a second current collector disposed on another side of the ion transporter, the second collector comprising
a first substrate;
carbon nanotubes grown on the first substrate;
silicon-containing matrix bonded to the carbon nanotubes and interacting with the ions.

8. An electrochemical cell as in claim 7 wherein the silicon-containing matrix comprises one of polycrystalline silicon and silicon compound.

9. An electrochemical cell as in claim 7 wherein the ion transporter comprises an electrolyte comprising lithium ions in a liquid solution.

10. An electrochemical cell as in claim 7 further comprising a separator configured to maintain physical separation between the first current collector and the second current collector, and allowing ions to pass through.

11. An electrochemical cell as in claim 7 wherein the silicon-containing matrix is configured to substantially withstand volumetric changes exhibited during cycling of the electrochemical cell.

12. An electrochemical cell as in claim 7 wherein the first current collector comprises
carbon nanotubes grown on a second substrate; and
lithium-containing material embedded between the carbon nanotubes.

13. A method for making an electrochemical cell, comprising
providing a first substrate;
forming a first current collector comprising
growing a first plurality of carbon nanotubes on the first substrate;
depositing silicon-containing material on the first plurality of carbon nanotubes.

14. A method as in claim 13 further comprising
depositing a seed layer on the first substrate to facilitate the growth of the first plurality of carbon nanotubes.

15. A method as in claim 13 further comprising
depositing a separator layer on the silicon-containing material.

16. A method as in claim 13 further comprising
forming a second current collector on a second substrate, comprising
growing a second plurality of carbon nanotubes on the second substrate;
depositing molten elemental sulfur on top of the second plurality of carbon nanotubes, wherein the elemental sulfur is driven to the second plurality of carbon nanotubes toward the second substrate.

17. A method as in claim 13 wherein the carbon nanotubes are grown on two opposite sides of the collector plate.

18. A method as in claim 13 wherein the carbon nanotubes are vertically aligned on the collector plate.

19. A method as in claim 13 wherein at least one of the carbon nanotubes and the silicon-containing material are grown by PECVD process.

20. A method as in claim 13 wherein the first substrate is flexible and rolled to a reel.
